(19) United States
(12) Patent Application Publication
(10) Pub. No.: US 2026/0169398 A1
(43) Pub. Date: Jun. 18, 2026

(54) LITHOGRAPHY SYSTEM COMPRISING A MEASUREMENT DEVICE

(71) Applicant: Carl Zeiss SMT GmbH, Oberkochen (DE)

(72) Inventors: Michael STOLZ, Oberkochen (DE); Timo LAUFER, Stuttgart (DE)

(21) Appl. No.: 19/535,737

(22) Filed: Feb. 10, 2026

Related U.S. Application Data
(63) Continuation of application No. PCT/EP2024/067119, filed on Jun. 19, 2024.

(30) Foreign Application Priority Data
Aug. 30, 2023 (DE) 10 2023 208 308.6

(51) Int. Cl. G03F 7/00; G02B 7/18

(52) U.S. Cl. CPC G03F 7/70891; G02B 7/1815; G03F 7/7085

(57) ABSTRACT

A lithography system, such as an EUV lithography system, comprises: a radiation source for generating used radiation; an optical element, such as a reflective optical element, having a surface provided for irradiation with the used radiation; and a measuring device for measuring a heat input, such as a temperature, at the surface of the optical element. The measuring device comprises a detection device for detecting radiation emanating from the surface of the optical element. The measuring device also comprises a lock-in amplifier. The lithography system comprises a heating device having at least one heating unit for irradiating the surface of the optical element with heating radiation. The heating device is designed for modulation, such as clocked modulation, for example pulsed modulation, of the heating radiation from the heating unit with which the surface of the optical element is irradiated.

### CROSS-REFERENCE TO RELATED APPLICATIONS

The present application is a continuation of, and claims benefit under 35 USC 120 to, international application No. PCT/EP2024/067119, filed Jun. 19, 2024, which claims benefit under 35 USC 119 of German Application No. 10 2023 208 308.6, filed Aug. 30, 2023. The entire disclosure of each of these applications is incorporated by reference herein.

### FIELD

The disclosure relates to a lithography system, such as an EUV lithography system, comprising: a radiation source for generating used radiation; an optical element, such as a reflective optical element having a surface provided for irradiation with the used radiation; and a measuring device for measuring a heat input, such as a temperature, at the surface of the optical element. The measuring device comprises a detection device for detecting radiation emanating from the surface of the optical element. The measuring device also comprises a lock-in amplifier. The lithography system may, for example, be a microlithographic projection exposure apparatus which serves for photolithographic production of semiconductor components and other structured components, or part of such a lithography apparatus, for example an illumination system or a projection optics unit of such a lithography apparatus. However, the lithography system may be a different optical arrangement for lithography, for example an inspection system, for example for inspection of masks, wafers or the like that are used in lithography. The lithography system may for example be an EUV lithography system which is operated with used radiation in the EUV wavelength range between approximately 5 nanometers (nm) and approximately 20 nm or 30 nm.

### BACKGROUND

Modern lithography optics or optical elements of projection exposure apparatuses expose structures in the plane of the wafer with a resolution of a few nanometers. The desired properties of such optical elements can be relatively stringent, for example in relation to the surface figure or the surface shape of the optical elements. This can be particularly true for lithography optics or optical elements for used radiation in the EUV wavelength range, which can involve a particularly precise surface shape, for example because all optical elements may be operated in reflection in the EUV wavelength range.

During the operation of an EUV lithography system, the optical elements operated in reflection are exposed to the used radiation in the EUV wavelength range and typically heat up, and this may result in a deformation of the optical elements. Thus, materials with a coefficient of thermal expansion which is as small as reasonably possible and which is minimal at a specific temperature, the so-called zero-crossing temperature (TZC), are desirable for use for the production of the main bodies of optical elements for the EUV wavelength range. The zero-crossing temperature of the main body material for an optical element can be set within certain limits during the production of the latter. In doing so, the zero-crossing temperature is typically chosen such that it corresponds to a desired operating temperature of the optical element. Hence, a respective reflective optical element may generate imaging aberrations at temperatures above or below the desired operating temperature.

In order to determine the actual temperature at the surface of a reflective optical element, which is also referred to below as a mirror for the sake of simplicity, it is possible to introduce temperature probes or temperature sensors into bores in the mirror main body. From the rear, the temperature probes can be brought to within a few millimeters (mm) of the mirror surface. Nevertheless, in general, the use of such temperature sensors does not allow determination of the actual temperature on the mirror surface. Although a back-calculation of the actual temperature of the mirror surface might be possible, it can be afflicted by a corresponding time lag owing to the distance between the temperature probe and the mirror surface. Hence, with the use of such temperature probes, it is generally not possible to determine short-term temperature signals from the proximity of the surface without a time lag.

However, determining the exact temperature at the mirror surface is useful as regards the capability of relatively accurately setting or controlling the desired operating temperature of the mirror, for example using direct, variable cooling of the mirror main body using a liquid-based cooling system integrated into the mirror main body or by irradiating the mirror surface with additional heating radiation.

DE102020203750A1 describes a device for detecting a temperature at a surface of an optical element for semiconductor lithography. The device comprises a temperature recording device in the form of an infrared camera, which detects a wavelength range between one micrometer (μm) and 15 μm or between 2 μm and 5 μm.

When detecting the temperature or the temperature distribution at a reflective surface, the temperature recording device described in DE102020203750A1 registers not only the thermal radiation emitted by the mirror surface but also the thermal radiation reflected off the mirror surface in the direction of the temperature recording device. For example, given an operating temperature of for example approximately 30° C. of the mirror with a mirror surface made of aluminum (emissivity ε approximately 0.05) and given a temperature of the housing or of the surrounding walls of approximately 22° C., an infrared or thermal imaging camera would tend to register the mirror image of the housing as seen from the temperature recording device but would hardly register the temperature distribution of the mirror surface itself owing to its low emissivity.

To avoid this effect, an element configured for temperature control is used in DE102020203750A1. The element is arranged in such a way that the thermal radiation detected by the temperature recording device and reflected by the reflection off the surface of the optical element is emitted by the element. The element may be cooled in order to render the ratio of the radiation reflected off the surface of the optical element to the thermal radiation emitted by the element as large as possible.

DE102020203753A1 describes a projection exposure apparatus for semiconductor lithography which comprises an optical element and a temperature recording device for detecting a temperature at a surface of the optical element via the electromagnetic radiation emanating from the surface of the optical element. The temperature recording device comprises an infrared camera and a lock-in amplifier for amplifying a clocked signature of the used radiation from the projection exposure apparatus used for the imaging process. The lock-in amplifier only amplifies the signal component containing the clocked signature of the used radiation. The background signal detected by the temperature recording device off components in the surroundings of the surface situated in the field of view of the camera therefore has little or no influence on the signal output by the lock-in amplifier.

### SUMMARY

The disclosure seeks to provide a lithography system which can allow for a contact-free measurement of a heat input, such as a temperature, at the surface of an optical element even for the case where a heat input that is not attributable to the used radiation or the background radiation is generated at the surface.

The disclosure provides a lithography system which comprises a heating device having at least one heating unit for irradiating the surface of an optical element with heating radiation, wherein the heating device is designed for modulation, such as clocked modulation, for example pulsed modulation, of the heating radiation from the heating unit with which the surface of the optical element is irradiated.

The lithography system described herein comprises a heating device having at least one heating unit which serves to irradiate the surface with heating radiation in addition to the used radiation used in the lithography system and in the process generates an additional heat input on the surface. In general, the heating unit(s) are used to bring the surface of the optical element to the desired operating temperature or keep the surface at the desired operating temperature. To this end, the heating radiation with which the surface of the optical element is irradiated may be controlled, for example. The heating unit(s) may also be used to heat the optical element before the lithography system is put into operation, i.e. before the optical element is irradiated with the used radiation. The wavelength or the wavelength range of the heating radiation typically differs from the wavelength or the wavelength range of the used radiation. The wavelength range of the heating radiation generally lies in the infrared wavelength range at wavelengths longer than approximately 1 μm, for example between approximately 1 μm and 1.6 μm.

As a result of the modulation of the heating radiation, the portion of blackbody radiation which is attributable to the heating radiation and which emanates from the surface, can be detected by the detection device and is generated by the temperature of the surface can be amplified with the aid of the lock-in amplifier and can be distinguished from a portion which is attributable to background radiation from the surroundings of the optical element and which is reflected or deflected in the direction of the measuring device or of the detection device at the surface of the optical element. As a result, it is possible to determine the heat input or the temperature at the surface of the optical element when the surface of the optical element is irradiated with the heating radiation only and not irradiated with the used radiation, as may be the case during breaks in operation of the lithography system.

In general, a lock-in amplifier serves the purpose of filtering the measurement signal in a targeted manner and removing the background signal from a measurement signal containing a large background signal and a small measurement signal. In the present case, the heating radiation, which corresponds to the measurement signal in this case, can be modulated in such a way that the lock-in amplifier is capable of filtering the measurement signal, i.e. the heating radiation detected by the detection device, in a targeted manner and removing the background signal, which is detected by the detection device and caused by the background radiation from the surroundings and optionally the used radiation, from the measurement signal. In the present case, the measurement signal can correspond to the radiation detected by the detection device.

The modulation can be implemented with the aid of a deterministic modulation signal. For example, the modulation may be clocked, i.e., with the aid of a constant-frequency modulation signal, for example by a sinusoidal or square-wave modulation signal. If the modulation signal is a clock signal, the latter can be switched or modulated between two states or optionally between more than two states. The surface of the optical element might not be irradiated with heating radiation during periodically recurring time intervals, the so-called clock pauses. In this case, the modulation can be pulsed, i.e. the heating radiation can be switched on and off in a clocked manner.

When the heating radiation is modulated, it is typically the power or the intensity of the heating radiation that is modulated, for example by virtue of a heating light source for generating the heating radiation from the heating unit being switched on and off in a clocked manner or being modulated in terms of its power. In general, other properties of the heating radiation may also be modulated as long as the modulation of the respective property allows the lock-in amplifier to amplify the modulation signal or optionally an intrinsic modulation of the heating radiation in a targeted manner. Should a clocked modulation signal be used, typically only the portion of the measurement signal having the set modulation frequency and/or phase of the modulation signal is amplified in the lock-in amplifier, which is why the background signal has little or no influence on the amplified signal output by the lock-in amplifier.

A deterministic modulation of the heating radiation described here differs from a variation, in the form of a closed-loop control, of the heating radiation used to irradiate the surface, within the scope of which control the heating power of the heating radiation emanating from the heating unit is modified in non-deterministic fashion on the basis of a current temperature, not known in advance, at the surface of the optical element.

In an embodiment, the radiation source is designed for modulation, such as clocked modulation, for example pulsed modulation, of the generated used radiation. The used radiation can be clocked or modulated with a predetermined pulse frequency. As described in detail below, the lock-in amplifier can be supplied with the modulation signal for the used radiation or optionally a signal detected by a radiation sensor as a reference signal. The thermal radiation caused by the used radiation can be amplified in this way with the aid of the lock-in amplifier, and the influence of the background radiation can be eliminated.

Should the surface of the optical element also be irradiated with heating radiation in addition to the used radiation amplified with the aid of the lock-in amplifier, the signal from the lock-in amplifier, which is attributable to the used radiation, cannot be used on its own for measuring the heat input at the surface since the heating radiation also generates a heat input at the surface which is accounted for within the scope of the measurement. Should the heating radiation not be modulated, the latter cannot be taken into account during the determination of the heat input because the heating radiation cannot be distinguished from the background radiation in this case, reducing the accuracy of the measurement of the heat input or of the temperature.

If the lock-in amplifier is used to amplify both the portion of the radiation which emanates from the surface, is detected by the detection device and is attributable to the used radiation and the portion of the detected radiation which is attributable to the heating radiation, then the overall heat input at the surface of the optical element can be measured or determined using these portions. For example, the sum of the two signals amplified by the lock-in amplifier of the used radiation and of the heating radiation can be used to determine the overall heat input. Within the scope of measuring the heat input, the modulation of the heating radiation need not necessarily differ from the modulation of the used radiation. For example, the modulation frequency of the used radiation may be in the order of 50 Hz. In the case of a radiation source for generating used radiation in the EUV wavelength range, the used radiation is typically pulsed, either during the generation of the used radiation or in a manner brought about in some other way, i.e., this is not continuous radiation, but rather used radiation is not generated or the generated radiation is filtered out within the radiation source during predetermined time intervals.

In a development of this embodiment, the modulation, e.g., the modulation frequency, of the used radiation from the radiation source differs from the modulation, e.g., the modulation frequency, of the heating radiation from the heating unit. It is possible to measure the overall heat input at the surface if the modulations of the used radiation and of the heating radiation are chosen to be identical (see above). However, despite the generally significantly different wavelength ranges of the heating radiation and of the used radiation, within the scope of the spatially resolved detection of (thermal) radiation emanating from the surface of the optical element, it is not possible to distinguish between a heat input at the surface attributable to the heating radiation and a heat input attributable to the used radiation, at least not in those portions of the surface of the optical element that are irradiated both with the used radiation and with the heating radiation. Different modulations of the heating radiation and of the used radiation can allow the heat input of the heating radiation at the surface to be distinguished from the heat input of the used radiation at the surface, and this may e.g. be expedient for controlling the temperature at the surface. In an alternative to the modulation frequencies or in addition, the used radiation and the heating radiation may also differ from each other by way of a different choice or modulation of their phases.

In an embodiment, the heating device is designed to supply the lock-in amplifier with a modulation signal, which is used to modulate the heating radiation, as a reference signal. In this embodiment, the modulation signal which is used for the irradiation with the heating radiation and which is supplied to the heating unit or the heating light source for the modulation can be also supplied to the lock-in amplifier as a reference signal. Should this be a clocked modulation signal, the lock-in amplifier only amplifies the portion of the measurement signal which comprises or correlates with the modulation frequency and/or the phase of the modulation signal.

Within the meaning of this application, the modulation signal supplied to the lock-in amplifier is also understood to mean a signal which is correlated with the modulation signal and which contains the information regarding the modulation frequency and/or the phase of the modulation signal. However, it is understood that the radiation source may also be designed accordingly to supply the lock-in amplifier with a modulation signal, which is used to modulate the used radiation, as a reference signal.

In an embodiment, the lithography system comprises a radiation sensor for detecting an intensity of the heating radiation with which the surface is irradiated by the heating unit, the radiation sensor being designed to supply the lock-in amplifier with a signal, which depends on the intensity of the detected heating radiation, as a reference signal. For example, the radiation sensor may be a photodiode or the like, which generates a signal in the form of a photocurrent which is proportional to the intensity of the heating radiation incident on the photodiode. It is understood that the lithography system may also comprise a radiation sensor for detecting an intensity of the used radiation with which the surface is irradiated by the radiation source, the radiation sensor being designed to supply the lock-in amplifier with a signal, which depends on the intensity of the detected used radiation, as a reference signal.

In an embodiment, the heating device comprises a first heating unit and a second heating unit for irradiating the surface of the optical element with heating radiation, with the heating device being designed for modulation, such as clocked modulation, for example pulsed modulation, of the heating radiation from the first heating unit and for modulation, such as clocked modulation, for example pulsed modulation, of the heating radiation from the second heating unit and with the modulation of the heating radiation from the first heating unit differing from the modulation of the heating radiation from the second heating unit. The heat input or the heat signature of the first and of the second heating units may differ from each other at the surface owing to the different modulation. This can be expedient to set or control the temperature at the surface as precisely as possible with the aid of the heating units. The heating radiation from the heating units for irradiation is typically infrared radiation with wavelengths longer than one μm, e.g., wavelengths in the order of approximately 1070 nm.

The entire surface of the optical element can be irradiated with the heating radiation from a heating unit, but the heating radiation from a heating unit is frequently directed at only a portion or sector of the surface, or only this portion or sector is irradiated therewith. Especially in the case of different portions or sectors of the surface being irradiated with respective heating radiation from the two heating units, it may be possible to optionally dispense with the different modulation for distinguishing between the heat inputs. For example, the surface may be measured in this case by a spatially resolving bolometer of the measuring device. To measure the surface, the measuring device may also comprise a plurality of photodiodes, in front of each of which there is an imaging optical unit that detects only a sector of the surface or optionally small portions of the surface in the style of pixels. In general, a thermal imaging camera may also be used provided the latter has a sufficient time resolution for lock-in thermography. In this way, the heat input from a heating unit can be associated with a respective portion of a thermal image, optionally a spatially highly resolved thermal image, of the surface.

The heating units themselves may comprise a heating radiation source, which is generally designed to generate heating radiation in the infrared wavelength range. However, the heating radiation may also be generated by an external heating radiation source and supplied to the heating units, for example by way of optical fibers or the like. It is understood that the heating device may also comprise more than two heating units, with which the surface of the optical element can be irradiated.

In an embodiment, the lithography system comprises a further optionally reflective optical element having a further surface provided for irradiation with the used radiation, with the heating device comprising at least one further heating unit for irradiating the surface of the further optical element with further heating radiation and with the heating device being designed for modulation, such as clocked modulation, for example pulsed modulation, of the further heating radiation from the further heating unit.

In this embodiment, the lithography system may comprise a further measuring device designed to measure a heat input, such as a temperature, at the further surface of the further optical element. The further measuring device may comprise a further detection device for detecting further radiation emanating from the further surface of the further optical element and a further lock-in amplifier, with which the heat input or the heat signature of the further heating radiation from the further heating unit, with which the further surface is irradiated, can be determined. It is understood that the heating device may comprise two or more further heating units, with which the further surface of the further optical element can be irradiated with further heating radiation.

In a development of this embodiment, the modulation of the heating radiation from the heating unit differs from the modulation of the further heating radiation from the further heating unit. Especially in the case where the optical element is a reflective optical element, the latter is generally situated in a highly reflective environment. In this case, some of the heating radiation from a heating unit, with which a reflective optical element is irradiated, can be reflected off the surface of the reflective optical element and, after multiple reflections, and can reach the surfaces of other reflective optical elements, where it can lead to a generally unwanted heat input. This phenomenon is also referred to as crosstalk.

If the heating units of different reflective optical elements are modulated or pulsed, then lock-in thermography or the respective lock-in amplifier can be used to determine the amount of absorbed crosstalk that originates from the respective reflective optical elements. To identify crosstalk, it may be desirable for the modulation of the heating units to be different for all reflective optical elements of the lithography system or optionally for a portion of the lithography system, for example a projection lens.

This does not necessarily mean that the heating units for a respective reflective optical element differs in terms of their modulation. However, if the modulations of the heating units for one and the same optical element differ, then it is possible to identify not only the optical element but also the heating unit which generates the crosstalk. To identify crosstalk, it is desirable if the modulation of the heating radiation from the heating unit(s) or the further heating unit(s) differs from the modulation of the used radiation.

To identify crosstalk, e.g., the modulation or a modulation signal from the further heating unit or a signal from a sensor unit for detecting the intensity of the further heating radiation may be supplied as a reference signal to the lock-in amplifier of the measuring device for the above-described optical element. In this case, the lock-in amplifier can amplify the portion of the detected radiation that can be traced back to the crosstalk caused by the further heating radiation from the further optical element at the surface of this optical element.

In an embodiment, the detection device for detecting the radiation emanating from the surface of the optical element is designed as a spatially resolving bolometer. In this case, the radiation detected by the detection device can be thermal radiation in the infrared wavelength range. The spatially resolving bolometer can allow contact-free detection—both near surface and with high temporal and spatial resolution—of the thermal radiation emanating from the surface of the optical element and hence allows an instantaneous measurement of the heat input or the temperature at the surface of the optical element. In general, the spatially resolving bolometer internally images the surface region in which the heat input or temperature should be measured onto a spatially resolving detector. The surface region may be the entire surface or a portion of the surface. The imaging process can be accomplished with the aid of optical units suitable for the wavelength range of the detected radiation.

In an embodiment, the detection device for detecting the radiation emanating from the surface of the optical element comprises at least one photodiode, such as a plurality of photodiodes. In general, it is desirable for the amplification via the lock-in amplifier to be performed on the analog signal, i.e., prior to any potential digitization which may reduce the resolution of the signal. It is therefore desirable for the detection device to make use of a detector which is not read in digitized form, as would be the case for e.g. a CCD chip, since the subsequent signal amplification should be performed in analog fashion. For example, a grid of photodiodes which are sensitive to the radiation to be detected and the analog signals of which are accessible can be used as the detector. If such a grid or array is integrated as a detector into a detection device in the form of the thermal imaging camera, then it is possible to image a respective portion of the surface of the optical element onto a photodiode with the aid of a suitable imaging optical unit.

The photodiodes may be controlled in such a way that what is known as a photocurrent can be measured at them, the latter being proportional to the intensity of the thermal radiation incident on the photodiode. The photocurrent from the photodiode can be supplied to the lock-in amplifier as an input signal. In addition, one or more reference signals correlating with the modulation of the used signal (see above) can be supplied to the lock-in amplifier at a reference input. For example, the photocurrent from a radiation sensor detecting the intensity of the used signal may serve as the reference signal, or the modulation signal may be used as the reference signal.

In general, it is possible for the radiation emanating from the surface to be detected in non-spatially-resolved fashion. In this case, the detection device may comprise e.g. a single photodiode as a detector, onto which the radiation emanating from the surface is imaged with the aid of suitable optical units. An arrangement of photodiodes, optionally in combination with an upstream optical unit, may also be used as a detection device. Such an arrangement of photodiodes also can help allow the spatially resolved detection of the heat input or of the temperature at the surface of the optical element, as described further above.

The detection device is typically designed for the detection of, or designed to be sensitive to, electromagnetic radiation having wavelengths in the wavelength range between approximately 1 μm and approximately 5 μm, optionally up to approximately 15 μm. The sensitivity and the resolution of the detector used can be optimized for temperatures between e.g. +20° C. and +150° C. as a result of choosing the spectral range detected by the detection device to be in the near infrared or optionally into the long-wave infrared. To determine the temperature on the basis of the detected electromagnetic radiation, it is possible to use the Stefan-Boltzmann law provided that the emissivity of the surface is known; the latter may be determined in advance, for example by calibration.

It is not mandatory for the detector to generate an analog signal for the lock-in amplifier if modern digital image processing is used. Within the meaning of this application, a lock-in amplifier is also understood to mean a digital circuit or corresponding software which assumes the function of an analog lock-in amplifier.

The measuring device can measure the respective heat input at the surface of the optical element on the basis of the signal which is attributable to the used radiation and is amplified by the lock-in amplifier and on the basis of the signal which is attributable to the heating radiation and is amplified by the lock-in amplifier. For this purpose, the measuring device may comprise an evaluation device realized in the form of suitable hardware and/or software. Amplification of the signals attributable to the used radiation and to the heating radiation may be implemented simultaneously in the lock-in amplifier, especially for the case where the used radiation and the heating radiation are instantaneous and synchronized in clocking. In this case, the entire heat input of the used radiation and of the heating radiation during a respective heat pulse can be measured by the lock-in amplifier.

The lock-in amplifier can also filter a non-cyclic baseline value of the background signal, which corresponds to the background temperature at the surface. Should the temperature be determined by way of the Stefan-Boltzmann law, the signal of the lock-in amplifier is proportional to T_{B}⁴−T_{A}⁴, where T_{B} denotes the temperature during the (heating) pulse and T_{A} denotes the background temperature of the surface. For example, a slowly responding temperature probe in a bore in the mirror main body can be used to determine the background temperature T_{A} of the surface. Should the temperature T_{A} be known, the (instantaneous) temperature T_{B} at the surface can be determined from the signal of the lock-in amplifier. It is also possible for the signal of the lock-in amplifier, which only measures the amplitude of the heat pulses, to be used as a control signal for the heating unit(s) of the heating device.

For this measurement or determination of the temperature, the measuring device typically can comprise an evaluation device, which may e.g. be designed in the manner of a digital or analog circuit. As described further above, the contribution of the background radiation can be eliminated when determining the temperature via the lock-in amplifier. Amplification by the time-division multiplex method is also possible. In this case, the used radiation and the heating radiation differ from each other in terms of at least one property, for example in terms of frequency or phase. In this case, the heating radiation and the used radiation may have different frequencies, for example. In this case, it is desirable for the frequencies not to be harmonically related to one another, i.e. not to represent integer multiples of one another. The heat input by the heating radiation and the heat input by the used radiation may also be distinguished from each other if the heating radiation and the used radiation have identical frequencies but different phases. In this case, different reference signals can be used for measuring the heat input by the used radiation and the heat input by the heating radiation.

In an embodiment, the detection device is designed to detect radiation emanating from the entire surface. In this case, the entire surface can be measured, for example with the aid of a spatially resolving bolometer, a plurality of photodiodes, in front of each of which there is an imaging optical unit, or optionally using a thermal imaging camera with high time resolution. In this way, the temperature at any location of the surface may be measured via the measuring device. In general, it is also possible to only detect radiation emanating from a part of the surface of the optical element via the detection device. Should this relate to an optical element comprising a reflective coating, the surface forms a boundary of the reflective coating to the surroundings of the optical element.

Further features and embodiments of the disclosure are evident from the following description of exemplary embodiments of the disclosure with reference to the figures of the drawing, which show certain details of the disclosure, and from the claims. The individual features can be realized in each case individually by themselves or as a plurality in any desired combination in a variant of the disclosure.

### BRIEF DESCRIPTION OF THE DRAWINGS

Exemplary embodiments are shown in the schematic drawings and are explained in the description which follows. In the drawings:

FIG. 1 schematically shows a meridional section through a projection exposure apparatus for EUV projection lithography;

FIG. 2 shows a schematic illustration of a DUV lithography apparatus comprising an illumination device and a projection lens;

FIG. 3 shows a schematic illustration of a mirror in a projection exposure apparatus, having a measuring device for measuring a heat input, for example a temperature, at a reflective surface of the mirror;

FIG. 4 shows a schematic illustration of a lock-in amplifier, which is supplied with a measurement signal containing a used signal and a background signal and supplied with a reference signal;

FIG. 5 shows a schematic illustration of a further mirror in a projection exposure apparatus, having a further measuring device;

FIG. 6 shows a schematic illustration of the time profile of a pulsed reference signal and a used signal;

FIG. 7 shows a schematic illustration of the time profile of the used signal from FIG. 6 and the heat propagation in the mirror at three different times;

FIG. 8 shows schematic illustrations of the spectrum of the radiation emanating from the surface of the reflective element at two different times; and

FIG. 9 shows a schematic illustration of three radiation sensors with three different wavelength filters when detecting thermal radiation at two different times.

### DETAILED DESCRIPTION

In the description of the drawings that follows, identical reference signs are used for identical or functionally identical components.

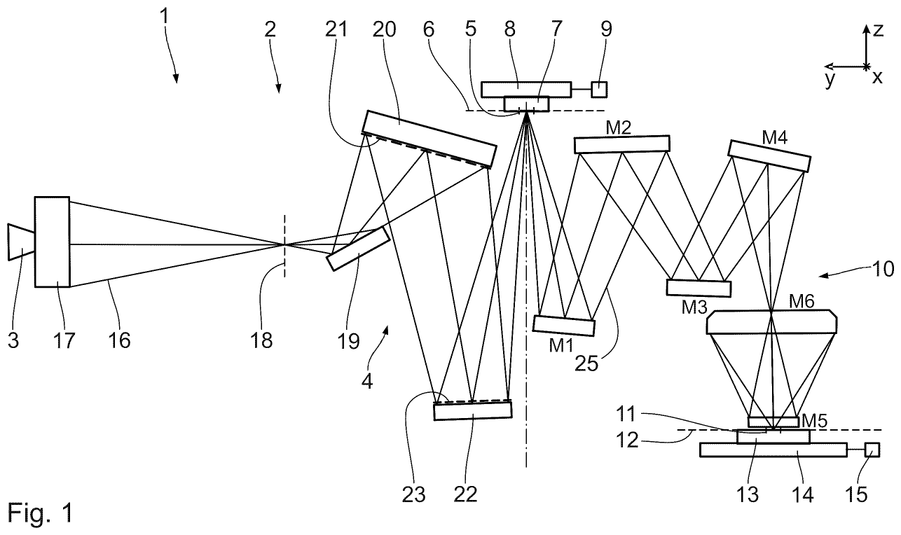

Certain constituent parts of an optical arrangement for EUV lithography in the form of a microlithographic projection exposure apparatus 1 are described by way of example below with reference to FIG. 1. The description of the basic setup of the projection exposure apparatus 1 and the constituent parts thereof should not be understood to have a limiting effect.

An embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable for example in a scanning direction by way of a reticle displacement drive 9.

By way of elucidation, FIG. 1 shows a Cartesian xyz coordinate system. The x-direction runs perpendicularly to the plane of the drawing into the latter. The y-direction runs horizontally, and the z-direction runs vertically. The scanning direction runs in the y-direction in FIG. 1. The z-direction runs perpendicularly in relation to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 that is arranged in the region of the image field 11 in the image plane 12. The wafer 13 is held by a wafer holder 14. The wafer holder 14 is displaceable, for example in the y-direction, by way of a wafer displacement drive 15. The displacement firstly of the reticle 7 via the reticle displacement drive 9 and secondly of the wafer 13 via the wafer displacement drive 15 can be synchronized with each other.

The radiation source 3 is an EUV radiation source. The radiation source 3 emits EUV radiation 16, which is also referred to below as used radiation, illumination radiation or illumination light. The used radiation has for example a wavelength in the range of between 5 nm and 30 nm. The radiation source 3 may be a plasma source, for example an LPP (Laser Produced Plasma) source or a GDPP (Gas Discharge Produced Plasma) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

Downstream of the collector mirror 17, the illumination radiation 16 propagates through an intermediate focus in an intermediate focal plane 18. The intermediate focal plane 18 may constitute a separation between a radiation source module, having the radiation source 3 and the collector mirror 17, and the illumination optics unit 4.

The illumination optics unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. In addition to that or in an alternative, the deflection mirror 19 may be embodied as a spectral filter that separates a used light wavelength of the illumination radiation 16 from extraneous light of a wavelength deviating therefrom. The first facet mirror 20 comprises a multiplicity of individual first facets 21, which are also referred to below as field facets. FIG. 1 illustrates only some of these facets 21 by way of example. In the beam path of the illumination optics unit 4, a second facet mirror 22 is disposed downstream of the first facet mirror 20. The second facet mirror 22 comprises a plurality of second facets 23.

The illumination optics unit 4 thus forms a doubly faceted system. This basic general is also referred to as a fly's eye integrator. The second facet mirror 22 is used to image the individual first facets 21 into the object field 5. The second facet mirror 22 is the last beam-shaping mirror or else actually the last mirror for the illuminating radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection system 10 is a doubly obscured optical unit. The projection optics unit 10 has an image-side numerical aperture which is greater than 0.4 or 0.5 and which may also be greater than 0.6 and which may be for example 0.7 or 0.75.

Just like the mirrors of the illumination optics unit 4, the mirrors Mi may have a highly reflective coating for the illumination radiation 16.

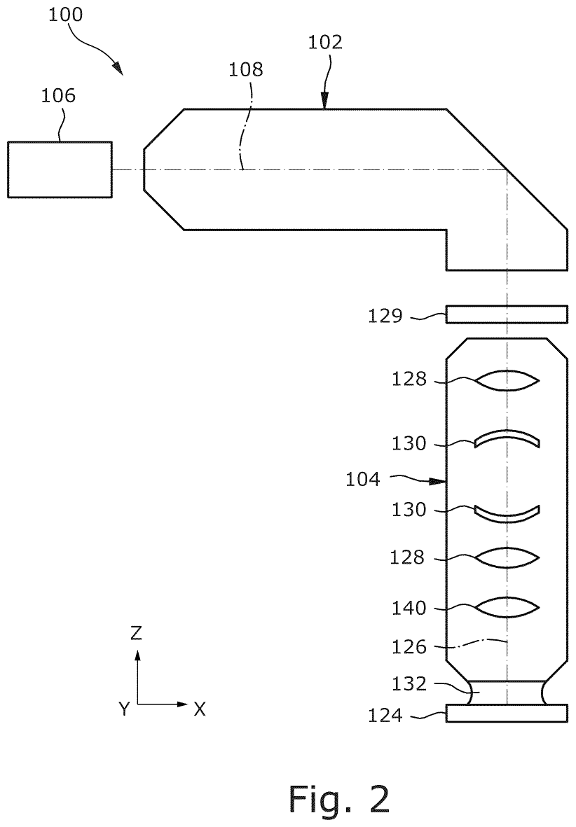

FIG. 2 shows a schematic view of a of a DUV projection exposure apparatus 100, which comprises a beam shaping and illumination device 102 and a projection lens 104. In this case, DUV stands for “deep ultraviolet” and denotes a wavelength of the work light of between 30 nm and 370 nm. The DUV projection exposure apparatus 100 comprises a DUV light source 106. For example, an ArF excimer laser that emits radiation 108 in the DUV range at for example 193 nm may be provided as the DUV light source 106.

The beam shaping and illumination device 102 illustrated in FIG. 2 directs the DUV radiation 108 onto a photomask 129. The photomask 129 is designed as a transmissive optical element and can be arranged outside the beam shaping and illumination device 102 and the projection lens 104. The photomask 129 comprises a structure of which a reduced image is projected onto a wafer 124 or the like via the projection lens 104.

The projection lens 104 comprises multiple lens elements 128, 140 and/or mirrors 130 for imaging the photomask 129 onto the wafer 124. In this case, individual lens elements 128, 140 and/or mirrors 130 of the projection lens 104 can be arranged symmetrically in relation to the optical axis 126 of the projection lens 104. It should be noted that the number of lens elements and mirrors of the DUV projection exposure apparatus 100 is not restricted to the number illustrated. More or fewer lens elements and/or mirrors can also be provided. Furthermore, the mirrors are generally curved on their front side for beam shaping purposes.

An air gap between the last lens element 140 and the wafer 124 can be filled by a liquid medium 132 having a refractive index>1. The liquid medium 132 can be high-purity water, for example. Such a set-up is also referred to as immersion lithography and has an increased photolithographic resolution.

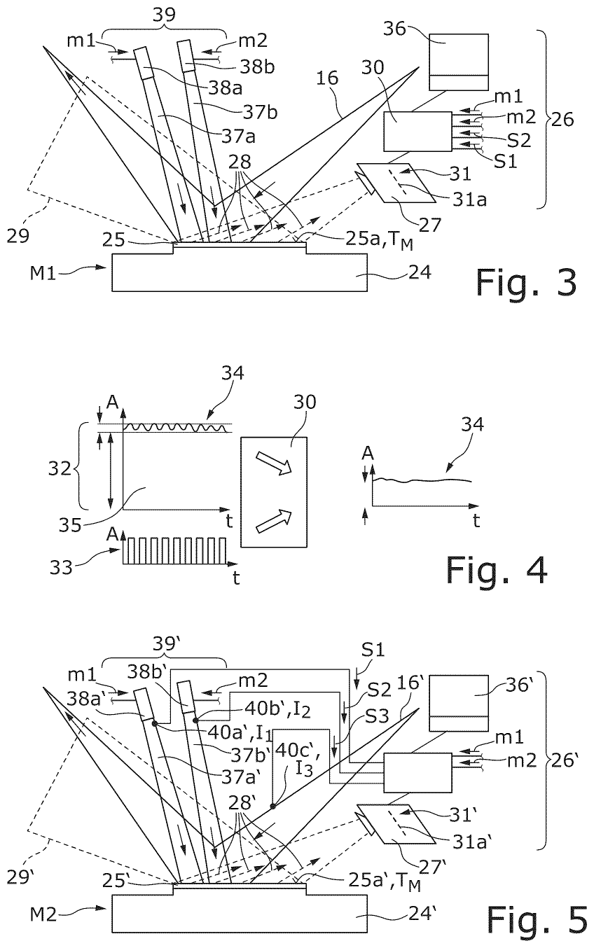

A temperature measurement at a mirror Mi in the projection system 10 of the projection exposure apparatus 1 of FIG. 1 is described below on the basis of FIG. 3. It is understood that such a temperature measurement may also be performed at one of the optical elements in the illumination system 2 of the projection exposure apparatus 1 or at one of the optical elements in the DUV projection exposure apparatus 100 illustrated in FIG. 2, for example at a lens element 128, 140 or a mirror 130 in the projection lens 104. FIG. 3 shows a reflective optical element in the form of the first mirror M1 in the projection system 10 of the projection exposure apparatus 1 of FIG. 1. The mirror M1 comprises a main body 24 formed from a material with a low coefficient of thermal expansion. The mirror M1 comprises a highly reflective coating 25, which is applied to the main body 24. In the example shown, where the used radiation 16 from the radiation source 3 is EUV radiation at a wavelength of 13.5 nm, the highly reflective coating 25 comprises alternating layers of silicon and molybdenum. A surface 25a at the top side of the reflective coating 25 forms a boundary to the surroundings, and it is irradiated with used radiation 16 during operation and reflects the used radiation 16, as evident from FIG. 3.

In general, a temperature T_{M} at the surface 25a of the mirror M1 can be measured by virtue of temperature sensors (not depicted here) being affixed in the main body 24 of the mirror M1 at a small distance of a few millimeters from the surface 25a of the mirror M1. However, such temperature sensors only allow the temperature T_{M} at the surface 25a to be measured with a certain time lag. This time lag during the temperature measurement leads to a significant error contribution in the surface figure deformation.

For the measurement, spatially resolved in the example shown, of a temperature T_{M} at the surface 25a of the mirror M1, more precisely of the reflective coating 25, the projection exposure apparatus 1 of FIG. 1 comprises a measuring device 26. In the example shown, the measuring device 26 comprises a detection device 27 serving to detect radiation 28 which emanates from the surface 25a of the mirror M1 and is indicated by dashed arrows in FIG. 3. The detection device 27 detects the radiation 28 situated within a field of view 29, indicated by dashed lines, in which the entire surface 25a of the mirror M1 is situated in the example shown. Alternatively, only a portion of the surface 25a of the mirror M1 can be detected via the detection device 27.

In the example shown, the detection device 27 is designed to detect radiation in the infrared wavelength range from approximately 1 μm to approximately 5 μm, optionally up to approximately 15 μm. In the example shown in FIG. 3, the detection device 27 is in the form of a spatially resolving bolometer. When measuring the temperature T_{M} at the surface 25a of the mirror M1, it is problematic that the field of view 29 of the detection device 27 does not only detect radiation 28 from the surface 25a itself but also detects radiation which comes from the highly reflective surroundings of the mirror M1 and is reflected off the surface 25a in the direction of the detection device 27.

Moreover, the temperature T_{M} to be measured at the surface 25a of the mirror M1, which may lie e.g. in the range between 22° C. and 40° C., does not differ significantly enough from the temperature in the surroundings of the mirror M1, which e.g. is at approximately 22° C. Therefore, the measuring device 26 cannot distinguish between the temperature of the surroundings reflected off the surface 25a and the temperature of the reflective surface 25a with a sufficient accuracy to achieve a temperature measurement accuracy of e.g. approximately 0.1 K.

What is exploited in the case of the measuring device 26 shown in FIG. 3 is that the used radiation 16 is not generated continuously by the radiation source 2 but in pulsed fashion, i.e. the radiation source 2 generates the used radiation 16 with a pulsed modulation with a pulse frequency of for example approximately 50 Hz, with which radiation pulses and pulse pauses alternate. In the example shown, the modulation of the used radiation 16 is used to amplify only the portion of the detected radiation 28 attributable to the used radiation 16 in a lock-in amplifier 30 of the measuring device 26 and to distinguish this portion from a portion that is attributable to the background radiation which is from the surroundings of the mirror M1 and reflected off the reflective surface 25a.

In FIG. 3, the lock-in amplifier 30 is designed for analog signal processing. Hence, it is desirable that a spatially resolving detector 31 attached to the detection device can be read out in analog fashion. For this purpose, the detector 31 in the example shown comprises a plurality of photodiodes 31a which are arranged in a grid arrangement and controlled in such a way that it is possible to measure a photocurrent at them, the photocurrent being proportional to the intensity of the infrared radiation 28 which is incident on the respective photodiode 31a and detected by the detection device 27 in the form of the spatially resolving bolometer. The detection device 27 comprises an optical unit (not depicted here), which images a respective portion of the surface 25a onto a photodiode 31a associated with this portion.

The photocurrent generated by the respective photodiode 31a forms a measurement signal 32, the time curve of which is depicted in FIG. 4 and which is supplied to a first input of the lock-in amplifier 30. A reference signal 33, which is a pulsed square-wave signal in the example shown and the time curve or amplitude A of which is also depicted in FIG. 4, is supplied to a second input of the lock-in amplifier 30. The measurement signal 32 includes a first portion in the form of a used signal 34 and a second portion in the form of a background signal 35, the latter having a significantly greater amplitude A than the used signal 34.

It is also evident from FIG. 4 that only the used signal 34—and not the background signal 35—is modulated with a constant frequency. Since the reference signal 33, which is pulsed with the same frequency, is supplied to the lock-in amplifier 30, the lock-in amplifier 30 only amplifies the used signal 34, which is modulated with the same frequency and optionally with the same phase as the reference signal 33. The used signal 34 amplified by the lock-in amplifier 30 is depicted to the right in FIG. 4.

In the example described here, the used signal 34 is the portion of the detected radiation 28 in the infrared range which is attributable to the used radiation 16 and detected by the detection device 27. The reference signal 33 is formed by a modulation signal which is also made available to the radiation source 2 for the purpose of the pulsed generation of the used radiation 16. Since the background signal 35 attributable to the background radiation does not correlate with the frequency of the used radiation 16, the portion of the measurement signal 32 attributable to the background radiation is not amplified by the lock-in amplifier 30.

The amplified used signal 34 is supplied to an evaluation device 36 of the measuring device 26, and the temperature T_{M} at the surface 25a of the mirror M1 is inferred by the evaluation device 36 on the basis of the amplified used signal 34. In addition to a rapidly fluctuating component, the background signal 35 also includes a non-cyclic component (baseline component), which is not amplified by the lock-in amplifier 30 either. Hence the lock-in amplifier 30 measures the magnitude or intensity of the difference between the temperature of the respective heat pulse and the background temperature. To determine the temperature T_{M} at the surface 25a of the mirror M1 with the aid of the Stefan-Boltzmann law, it is therefore desirable to additionally determine the non-cyclic component of the background signal 35, which corresponds to the temperature at the surface 25a that is not attributable to the cyclic heat input. In order to determine the time-averaged temperature at the surface 25a, the evaluation device 36 may for example use the above-described, slowly responding temperature sensors integrated into the main body 24 of the mirror M1. Additionally, the measuring device 26 may be calibrated and characterized before the projection exposure apparatus 1 is put into operation, for the purposes of which e.g. pulsed heat sources with a known power can be used.

Even in the projection exposure apparatus 1 of FIG. 1, which has non-cooled walls in the surroundings of the mirror M1 and correspondingly pronounced background radiation, it is still possible to measure the temperature T_{M} in the vicinity of the surface, which was generated by the used radiation 16, very accurately by a photometric mechanism and without contact using lock-in thermography as described above. However, this only applies in the case where the temperature T_{M} at the surface 25a of the mirror M1 is attributable only to the heat input by the used radiation 16 and not additionally attributable to a heat input into the surface 25a by other heat sources.

In the example shown in FIG. 3, the surface 25a of the mirror M1 is irradiated with heating radiation 37a, 37b from a first heating unit 38a and a second heating unit 38b of the heating device 39, in addition to the used radiation 16. In the example shown, the heating units 38a,b are designed to direct the heating radiation 37a,b at different portions of the surface 25a of the mirror M1. The heating units 38a,b may be embodied in different ways, for example in the form of sector heaters or in the form of heating heads. The heating radiation 37a,b may be generated by a respective heating radiation source in each heating unit 38a,b; however, it is also possible that the heating radiation 37a,b is generated by one or more heating radiation sources in the heating device 39 which are arranged at a distance from the heating units 38a,b and supplied to the heating units 38a,b by way of e.g. optical fiber cables or the like.

For example, the heating units 38a,b can be used to anticipate the initial heating of the mirror M1 before the exposure operation of the projection exposure apparatus 1 or to preheat the mirror M1 for the exposure operation. The heating units 38a,b may also serve to homogenize an inhomogeneous temperature distribution at the surface 25a of the mirror M1, which is caused by a respective illumination setting, by way of complementary heating. The heating units 38a,b may also be used to compensate for temporal and spatial temperature fluctuations of the surface 25a of the mirror M1, which for example arise on account of a change from a bright to a dark reticle.

It is also evident from FIG. 3 that the surface 25a comprises portions that are only heated by the used radiation 16 and portions in which both the used radiation 16 and the heating radiation 37a, 37b are incident on the surface 25a. In general, it is also possible that portions of the surface 25a are heated only by the heating radiation 37a, 37b and not by the used radiation 16.

Especially in the portions of the surface 25a heated both by the used radiation 16 and by the heating radiation 37a,b, the temperature T_{M} at the surface 25a depends not only on the intensity or the power of the used radiation 16 but also on the intensity or the power of the heating radiation 37a,b with which the surface 25a is irradiated. In order to determine the temperature T_{M} at the surface 25a in these portions, the heating radiation 37a,b from the heating units 38a,b, with which the surface 25a is irradiated, is also modulated, or pulsed to be more precise. A modulation signal m1, m2 supplied to the heating units 38a,b for this purpose is also supplied as a reference signal 33 to the lock-in amplifier 30 in the example shown in FIG. 3. In the manner described in connection with FIG. 4, the lock-in amplifier 30 may produce an amplified used signal 34 which corresponds to the portion of the detected radiation 28 that is attributable to the heating radiation 37a,b from the heating units 38a,b or from a respective heating unit 38a,b.

The modulation signals m1, m2 and the modulation signal for the used radiation 16 may be identical. Although the temperature T_{M} in a respective portion of the surface 25a on which the used radiation 16 and the heating radiation 37a,b are incident can be determined by the evaluation device 36 in this case, the portions of the used radiation 16 and of the heating radiation 37a,b cannot be distinguished from each other. However, such a distinction is desirable for controlling the heating units 38a,b in order to generate a desired temperature distribution at the surface 25a of the mirror M1.

If the modulation of the heating radiation 37a,b differs from the modulation of the used radiation 16, then the respective portions can be amplified separately by the lock-in amplifier 30 and can be distinguished from each other in this way. For this purpose, it is sufficient for the two modulation signals M1, M2 for the heating units 38a,b to differ from the modulation signal for the used radiation 16. For example, the two modulation signals m1, m2 may have a modulation frequency that deviates from the modulation frequency of the used radiation 16 of e.g. 50 Hz. Alternatively, the two modulation signals m1, m2 for the heating radiation 37a,b may be clocked with a different phase than the modulation signal for the used radiation 16.

It is desirable for the modulation signals m1, m2 for the two heating units 38a,b to differ from each other. In this case, it is possible with the aid of the lock-in amplifier 30 to distinguish between the heat inputs of the two heating units 38a,b at the surface 25a. This is particularly desirable if—unlike what is depicted in FIG. 3—the heating radiation 37a,b from the two heating units 38a,b is used to irradiate a common portion of the surface 25a. For example, the two modulation signals m1, m2 may have different modulation frequencies for this purpose.

FIG. 5 shows a further mirror in the form of the second mirror M2 in the projection optics unit 10 of the projection exposure apparatus 1 in FIG. 1, having a further measuring device 26′ for measuring a temperature T_{M}′ at a further reflective surface 25a′ of the further mirror M2. The further measuring device 26′ is embodied like the measuring device 26 shown in FIG. 3. The heating device 39, which serves to heat all mirrors M1 to M6 in the projection optics unit 10, has two further heating units 38a′, 38b′ in the example shown, and these are embodied so that the further surface 25a′ of the further mirror M2 can be irradiated with further heating radiation 37a′, 37b′. The two further heating units 38a′, 38b′ are also used by the heating device 39 for the pulsed modulation of the further heating radiation 37a′, 37b′, with which the further surface 25a′ is irradiated.

It is also evident from FIG. 5 that a first radiation sensor 40a′ for detecting an intensity I₁ of the further heating radiation 37a′ is affixed at the lateral edge of the beam cross section of the further heating radiation 37a′ emitted by the first further heating unit 38a′. Accordingly, a second radiation sensor 40b′ for detecting an intensity I₂ of the further heating radiation 37b′ is affixed at the lateral edge of the beam cross section of the further heating radiation 37b′ emitted by the second further heating unit 38b′. A third radiation sensor 40c′ is affixed at the lateral edge of the beam cross section of the used radiation 16 and serves to detect the intensity I₃ of the used radiation 16 with which the further surface 25a′ is irradiated. The three radiation sensors 40a-c′ are photodiodes which each generate a signal S1, S2, S3 which depends on the respective detected intensity I₁, I₂, I₃ and which is in the form of a photocurrent proportional to the respective intensity I₁, I₂, I₃, and these signals are supplied to the further lock-in amplifier 30′ in the further measuring device 27′ as respective reference signals 33. It is understood that the reference signal(s) 33 of the lock-in amplifier 30 of FIG. 3 may be provided analogously by three radiation sensors (not depicted here).

The modulation of the further heating radiation 37a′ from the first further heating unit 38a′ differs from the modulation of the further heating radiation 37b′ from the second further heating unit 38b′ so that the heat inputs of the respective further heating units 38a′, 38b′ at the further surface 25a′ can be distinguished from each other.

Moreover, the modulation of the heating radiation 37a, 37b from the first and second heating units 38a, 38b which is incident on the surface 25a of the first mirror M1 shown in FIG. 3 differs from the modulation of the further heating radiation 37a′, 37b′ incident on the further surface 25a′ of the second mirror M2. In this way, further heating radiation 37a′, 37b′ from the further heating units 38a′, 38b′ which is reflected off the further surface 25a′ of the second mirror M2 and reaches the surface 25a of the first mirror M1 by way of multiple reflections can be detected or identified with the aid of the measuring device 26. For this purpose, i.e. for determining the heat input generated at the surface 25a of the first mirror M1 by the heating radiation 37a′, 37b′ used to irradiate the further surface 25a′ of the second mirror M2, the signals S1, S2 generated by the first radiation sensor 40a′ and by the second radiation sensor 40b′ are supplied to the lock-in amplifier 30 in the measuring device 26 as reference signals 33.

It is understood that the procedure described in connection with FIG. 5 may be carried out accordingly at the four further mirrors M3 to M6 in the projection system 10 in order to ascertain the crosstalk of all other mirrors M2 to M6 at the surface 25a of the first mirror M1. It is furthermore understood that this procedure may be carried out accordingly at the other mirrors M2 to M6 as well. It is furthermore understood that the temperature measurement performed in the manner described above may also be carried out for mirrors which, in addition to the heating, are cooled with the aid of direct cooling in the main body of the respective mirror.

In the manner described above, it is possible to carry out a contact-free temperature measurement both—near the surface and with high temporal and spatial resolution—of the surfaces of optical elements in lithography systems 1, 100 in the case of surfaces which are heated by the used radiation and additionally by—optionally controllable—heating radiation. The temperature measurement may serve to improve controlling the temperature at the surfaces of the mirrors. Using lock-in thermography, as described above, in combination with the heating of the optical elements with the aid of the heating radiation, the optical elements may also be used as manipulators, e.g. for correcting the wavefront of the used radiation 16.

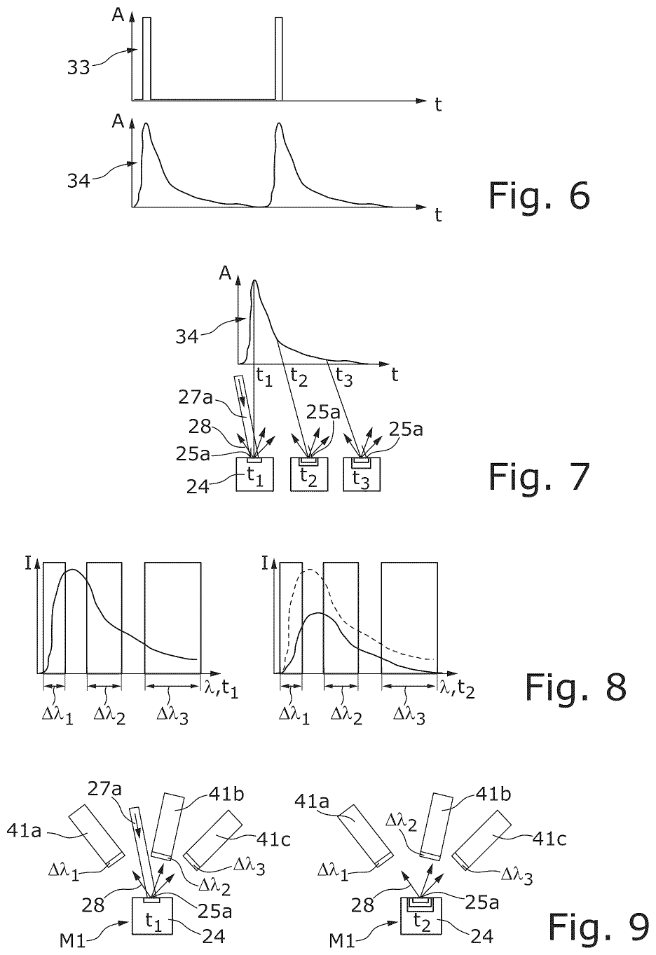

Furthermore, a suitable choice of the phase relationship between the reference signal 33 and the used signal 34 (cf. FIG. 6) allows different aspects of the used signal 34 to be detected, as described below on the basis of FIG. 7. The curve of the used signal 34 shown in FIG. 7, i.e. the thermal radiation from the surface 25a which is not attributable to background radiation, has a temporal relationship with the intensity pulses of the pulsed used radiation 16 or of the pulsed heating radiation 37a, 37b. The amplitude A of the used radiation 34 shown in FIG. 7 is linked to the instantaneous temperature T_{M} in the vicinity of the surface before the heat pulse of the used radiation 16 or of the heating radiation 37a,b can be dissipated into the underlying material of the main body 25. The temporal decay of the curve of the used signal 34 shown in FIG. 7 is linked to the temperature of the underlying layers and the heat conduction, the heat capacity and the thermal radiation of the materials. The information regarding the behavior of the thermal conduction and the heat capacity can be used to verify finite element models for the thermal conduction within the mirror M1. For example, the thermal resistance of the reflective coating 25 and the thermal resistance between the reflective coating 25 and the main body 24, which may be embodied e.g. in the form of titanium-doped quartz glass, can be ascertained or quantified in this way.

FIG. 7 illustrates this temporal behavior on the basis of three different times t₁, t₂, t₃. At the first time t₁, a pulse of heating radiation 37a irradiates a portion of the surface 25a, wherein a small volume, represented by a rectangle, below the surface 25a is heated. As a result of heat conduction, the heated volume increases at the two later times t₂, t₃, with the temperature in the heated volume decreasing at the same time. By varying the phase with respect to the reference signal 33, it is possible to measure the curve of the used signal 34 in general, wherein the temporal resolution is in the order of the length of the pulses of the used radiation 16 or of the heating radiation 37a, 37b.

The temperature of the irradiated surface layers can be inferred on account of the Stefan-Boltzmann law since the thermal radiation detected by the detection device 27 is proportional to the heat flow emitted at the surface 25a:

$$\dot{Q} = εσ {AT}^{4} ,$$

where ε denotes the emissivity of the surface 25a, σ=5.67 10⁻⁸ W/(m² K⁴) denotes the Stefan-Boltzmann constant and A denotes the area of the radiating surface.

FIG. 8 and FIG. 9 describe a further option for measuring the temperature T_{M} at the surface 25a of the mirror M1. In the example shown in FIG. 8 and FIG. 9, use is made of the fact that the temperature T_{M} at the surface 25a of the mirror M1 can also be measured on the basis of the position of the blackbody spectrum emitted by a body, e.g. the surface 25a of the mirror M1, as a function of the wavelength λ (Wien's law, Planck's law of radiation). In order to determine the temperature T_{M} in this way, the example illustrated in FIG. 9 provides for three radiation sensors 41a-c in the surroundings of the mirror M1 in order to detect a respective portion of the radiation 28 emanating from the surface 25a of the mirror M1. In the example shown, the radiation sensors 41a-c each comprise a wavelength filter, which passes a respective wavelength range Δλ₁, Δλ₂, Δλ₃ to a photodiode of the radiation sensors 41a-c. Each of the three radiation sensors 41a-c is therefore sensitive to a different wavelength range Δλ₁, Δλ₂, Δλ₃ of the blackbody radiation. Thus, the temperature T_{M} at the surface 25a can be inferred from the relative intensity I or amplitude of the radiation detected in the respective wavelength range Δλ₁, Δλ₂, Δλ₃. In general, two radiation sensors 41a, 41b thus suffice for the determination of the temperature T_{M}, but a greater number of radiation sensors is desirable in view of increasing the accuracy of the temperature measurement.

FIG. 8 and FIG. 9 show the mirror M1 on the left-hand side, in each case at a first time t₁, at which the surface 25a of the mirror M1 is irradiated with heating radiation 37a. The irradiated surface 25a of the mirror M1 has a very low back-penetration depth for thermal radiation arising below the surface 25a of the mirror M1. However, the thermal radiation from the layers located below the surface 25a within a few nanometers also reaches the radiation sensors 41a-c. Thus, in general, the thermal radiation 28 at the first time t₁, at which the heating radiation 37a is incident on the surface 25a, may originate from a different depth than the thermal radiation 28 which is incident on the radiation sensors 41a-c at a second, later time t₂. This leads to a change in the emissivity of the surface 25a from the first time t₁ to the second time t₂, as may be identified on the basis of the illustrations to the left in FIG. 8 and to the right in FIG. 8. The information regarding this change in the emissivity P of the surface 25a may also be ascertained by way of the variation of the phase at the lock-in amplifier 30. A layer degradation of the layers of the reflective coating 25 may be detected and optionally quantified on the basis of the change in emissivity c.

What is claimed is:

1. A lithography system, comprising:
a first reflective optical element comprising a surface configured to be irradiated with used radiation;
a heating device comprising a first heating unit configured to irradiate the surface of the first reflective optical element with a first heating radiation; and
a measuring device configured to measure a heat input at the surface of the first reflective optical element, the measuring device comprising:
a detection device configured to detect the first heating radiation emanating from the surface of the first reflective optical element; and
a lock-in amplifier,
wherein the heating device is configured to supply the lock-in amplifier with a modulation signal useable to modulate the first heating radiation.

2. The lithography system of claim 1, wherein the measuring device is configured to measure a temperature at the surface of the first reflective optical element.

3. The lithography system of claim 1, wherein the modulation of the first heating radiation comprises a clocked modulation.

4. The lithography system of claim 1, wherein the modulation of the first heating radiation comprises a pulsed modulation.

5. The lithography system of claim 1, further comprising a radiation source configured to generate the used radiation, wherein lithography system is configured to modulate the used radiation.

6. The lithography system of claim 5, wherein the modulation of the used radiation differs from the modulation of the first heating radiation.

7. The lithography system of claim 5, wherein the modulation of the used radiation comprises a clocked modulation.

8. The lithography system of claim 5, wherein the modulation of the used radiation comprises a pulsed modulation.

9. The lithography system of claim 1, further comprising a radiation sensor configured to detect an intensity of the first heating radiation with which the surface is irradiated by the first heating unit, wherein the radiation sensor is configured to supply the lock-in amplifier with a signal that depends on the intensity of the detected first heating radiation.

10. The lithography system of claim 1, wherein:
the heating device further comprises a second heating unit configured to irradiate the surface of the optical element with a second heating radiation;
the lithography system is configured to modulate the first heating radiation with a first modulation;
the lithography system is configured to modulate the second heating radiation with a second modulation; and
the first modulation is different from the second modulation.

11. The lithography system of claim 1, further comprising a second reflective optical element, wherein:
the second reflective optical element comprises a surface configured to be irradiated with the used radiation;
the heating device further comprises a second heating unit configured to irradiate the surface of the second reflective optical element with a second heating radiation; and
the lithography system is configured to modulate the second heating radiation.

12. The lithography system of claim 11, wherein the modulation of the first heating radiation differs from the modulation of the second heating radiation.

13. The lithography system of claim 1, wherein the detection device comprises a spatially resolving bolometer.

14. The lithography system of claim 1, wherein the detection device comprises a photodiode.

15. The lithography system of claim 1, wherein the detection device comprises a plurality of photodiodes.

16. The lithography system of claim 1, wherein the detection device is configured to detect the first heating radiation emanating from the entire surface.

17. The lithography system of claim 1, wherein the used radiation comprises EUV radiation.

18. The lithography system of claim 17, further comprising:
an illumination optics; and
a projection lens,
wherein:
the illumination optics is configured to illuminate an object field in an object plane of the projection lens with the used radiation;
the projection lens is configured to image the object field into an image field in an image plane of the projection lens; and
at least one member selected from the group consisting of the illumination optics and the projection lens comprises the first reflective optical element.

19. The lithography system of claim 1, further comprising:
an illumination optics; and
a projection lens,
wherein:
the illumination optics is configured to illuminate an object field in an object plane of the projection lens with the used radiation;
the projection lens is configured to image the object field into an image field in an image plane of the projection lens; and
at a member selected from the group consisting of the illumination optics and the projection lens comprises the first reflective optical element.

20. A method of using an apparatus comprising an illumination system and a projection lens, the method comprising:
using the illumination unit to illuminate an object in an object field in an object plane of the projection lens; and
using the projection lens to image the illuminated object into an image field in an image plane of the projection lens,
wherein a member selected from the group consisting of the illumination optics and the projection lens comprises the first reflective optical element.
